(19) United States
(12) Patent Application Publication
(10) Pub. No.: US 2014/0060625 A1
(43) Pub. Date: Mar. 6, 2014

(54) SOLAR MODULE FRAME

(71) Applicant: PPG INDUSTRIES OHIO, INC., Cleveland, OH (US)

(72) Inventors: Richard A. Beuke, Pittsburgh, PA (US); Michael J. Buchanan, Cranberry Township, PA (US)

(73) Assignee: PPG INDUSTRIES OHIO, INC., Cleveland, OH (US)

(21) Appl. No.: 14/017,449

(22) Filed: Sep. 4, 2013

Related U.S. Application Data
(60) Provisional application No. 61/696,846, filed on Sep. 5, 2012.

(51) Int. Cl. H01L 31/042; H01L 31/0203

(52) U.S. Cl. CPC H01L 31/0424; H01L 31/0203
USPC 136/251; 136/259

(57) ABSTRACT

A framed solar module includes a solar module having solar cells between a pair of sheets. The solar module is mounted in a frame, preferably a closed frame having a continuous base, and V-shaped cut outs or partially V-shaped in the upright legs where corners of the solar module are expected. A layer of a pliable moisture resistant sealant is provided between inner surface of the frame and the peripheral edge, and the marginal edge portions, of the solar module. A spacer, e.g. but not limited to a plurality of spaced protuberances formed on the inner surface of the dosed frame engage the outer surface of the solar module to provide the layer with a uniform thickness between the frame and the solar module.

### RELATED PATENT APPLICATION

This application claims the benefit of the filing date of U.S. Provisional Application Ser. No. 61/696,846 filed on Sep. 5, 2012 in the names of Richard A. Beuke and Michael J. Buchanan for a “Solar Module Frame”. Application Ser. No. 61/696,846 in its entirety is hereby incorporated by reference.

### BACKGROUND OF THE INVENTION

1. Field of the Invention

This invention relates to a metal or plastic frame to protect the article within the frame, e.g. but not limited to a solar module; to stack the framed solar modules for shipment and storage, and to mount the framed solar module to face a source of solar energy, and more particularly, to a frame mounting marginal and peripheral edge portions of a laminated solar module, the frame having raised areas to set the thickness of a sealant layer between the inside surface of the frame and the marginal and peripheral edge portions of the solar module, and in another non-limited embodiment of the invention, the frame includes a retention member or legs to mount the framed solar module for shipment, storage and use.

2. Discussion of the Presently Available Technology

A typical solar module includes two or more sheets, one of which is a transparent sheet and usually a glass sheet, laminated together to provide a single integrated structure having components organized between the sheets to convert solar energy to electric energy. A frame usually made of extruded metal, e.g. but not limited to steel and/or aluminum is mounted over the peripheral edge, and over the marginal edge portions of the solar module to protect the edges of the module during shipping, storage and use. Typical solar modules incorporate extruded metal frames to perform multiple functions. The frame (1) provides strength to stiffen the solar module under wind and/or snow loads, (2) helps seal the laminated solar module, (3) protects the glass edges of the module from damage during transit, installation and operation, and (4) provides a platform for mounting the module for shipment, storage and use.

In one arrangement, the present frames are made up of 8 pieces: four linear extruded side sections and four corner keys to join the pieces together. Some module manufacturing lines automate the installation of these frames, but the operation requires some pre-work to install the keys and stage the frame sections into the installation equipment or into magazines to feed that equipment. In another arrangement, the frames are made up of four linear extruded side sections, each section having mitered ends with the mitered ends of adjacent side sections meeting at a corner of the solar module. Optionally a sealant is employed to prevent or reduce moisture penetration between the frame and the module. The sealant can be in the form of a double sided tape having layers of sealant, e.g. but not limited to, a moisture resistance or moisture impervious adhesive, or a pliable layer of a moisture resistant or moisture impervious adhesive,

Although the frames presently available for framing solar modules and the method of mounting the frames on the solar modules are acceptable, there are drawbacks. More particularly, one of the drawbacks of the present frame technology is the lack of providing techniques for controlling the thickness of the pliable layer of the moisture resistant adhesive or sealant to provide a sealant layer having a uniform predetermined thickness. As is appreciated, sealant layers of non-uniform thickness provide random protection against moisture penetration, and it would be advantageous to provide a frame that has provisions to provide a sealant layer having a uniform predetermined thickness sufficient to prevent moisture penetration.

### SUMMARY OF THE INVENTION

The invention is directed to a framed solar module, including, among other things, a solar module comprising an energy converter between a pair of sheets laminated together, the solar module having a peripheral edge, and marginal edge portions, wherein the energy converter converts solar energy to non-solar energy; a frame having a base, a first leg, a second leg, a first end and a second end, wherein the base, the first leg and the second leg are joined together with the first leg and the second leg in facing relationship to, and spaced from, one another to provide the frame with a U-shape cross section to mount the frame over the peripheral edge, and the marginal edge portions, of the solar module, wherein the first end and the second end of the frame are joined together and the base of the frame is continuous from the first end to the second end of the frame; a layer of a pliable adhesive and/or a moisture resistant sealant between inner surface of the frame and the peripheral edge, and the marginal edge portions, of the solar module, and a spacer acting on the frame to limit movement of the frame toward the peripheral edge, and the marginal edge portions, of the solar module to provide the layer of the pliable adhesive and/or a moisture resistant sealant with a uniform thickness between the frame and the solar module.

The invention is also directed to a framed solar module including, among other things, a first solar module comprising an energy converter between a pair of laminated sheets, wherein the energy converter converts solar energy to non-solar energy, and a frame having a first leg member, a second leg member, a third leg member, a first end, a second end, and a retention leg member wherein the first leg member and the third leg member are joined to the second leg member with the first leg member and the third leg member in facing relationship to one another and spaced from one another to provide a first sub frame having an inner channel, wherein the marginal edge portions and the peripheral edge of the solar module are retained in the inner channel of the first sub frame and, wherein outer surface of the base of the first sub frame lies in a first plane and outer surface of the retention leg member lies in a second plane, the first plane and the second plane generally parallel to one another, with the retention leg member connected to the first sub frame and extending away from the solar module retained in the inner channel of the first sub frame to provide a cavity sized to receive a second sub frame of a second framed module or a stack retention base.

Further, the invention is directed to a method of mounting a solar module to receive solar energy. The method includes, among other things, constructing a framed solar module including, among other things, a first solar module comprising an energy converter between a pair of laminated sheets, wherein the energy converter converts solar energy to non-solar energy, and a frame having a first leg member, a second leg member, a third leg member, a first end, a second end, and a retention leg member wherein the first leg member and the third leg member are joined to the second leg member with the first leg member and the third leg member in facing relationship to one another and spaced from one another to provide a sub frame having an inner channel, wherein the marginal edge portions and the peripheral edge of the solar module are retained in the channel of the sub frame and, wherein outer surface of the base of the sub frame lies in a first plane and outer surface of the retention leg member lies in a second plane, the first plane and the second plane generally parallel to one another, with the retention leg member connected to the sub frame and extending away from the retained solar module to provide a cavity sized to receive a mounting block of an array of mounting blocks; constructing an array of mounting blocks facing or tracking a source of solar energy, each of the mounting blocks having a predetermined shape and dimensions to fit into the cavity provided by the retention leg member of the first sub frame: mounting a framed solar module on each of the mounting blocks with the mounting block positioned in the cavity of the retention leg member, and securing the framed solar module to the mounting block.

### BRIEF DESCRIPTION OF THE DRAWING

FIG. 1 is an isometric view of a prior art solar module.

FIG. 2 is an isometric view of a prior art framed solar module.

FIG. 3 is an isometric view of a non-limited embodiment of a segment of a frame of the invention.

FIG. 4 is view similar to the view of FIG. 2 showing a framed solar module of the invention.

FIG. 5 is an isometric view of a segment of a frame of the invention illustrating a non-limiting embodiment of a locking arrangement of the invention.

FIG. 6 is a partial cross sectional side view of a prior art framed solar module.

FIG. 7 is a view similar to the view of FIG. 6 showing a non-limited embodiment of a framed solar module of the invention.

FIG. 8 is a view similar to the view of FIG. 6 showing another non-limited embodiment of a framed solar module of the invention.

FIGS. 9A and 9B illustrate non-limiting embodiment of process steps of the invention for making non-limited embodiment of a corner of a frame of the invention.

FIG. 10 is an isometric view of a solar module having a frame of the invention applied to a solar module in accordance to the teachings of the invention.

FIG. 11 is a segmented cross sectional side view of a framed solar module of the invention mounted on a support frame.

FIG. 12 is a plan elevated view of a stack of framed solar modules, stacked in accordance to the invention.

FIG. 13 is a view taken along lines 13-13 of FIG. 12.

FIGS. 14A-14E illustrate non-limiting embodiment of process steps of the invention for making a non-limited embodiment of a frame of the invention having a retention member for stacking framed modules of the invention.

FIG. 15 is a view similar to the view of FIG. 13 showing another non-limited embodiment of the invention to stack solar modules.

### DETAILED DESCRIPTION OF THE INVENTION

As used herein, spatial or directional terms, such as “left”, “right”, “inner”, “outer”, “above”, “below”, and the like, relate to the invention as it is shown in the drawing figures. However, it is to be understood that the invention can assume various alternative orientations and, accordingly, such terms are not to be considered as limiting. Further, as used herein, all numbers expressing dimensions, physical characteristics, processing parameters, quantities of ingredients, reaction conditions, and the like, used in the specification and claims are to be understood as being modified in all instances by the term “about”. Accordingly, unless indicated to the contrary, the numerical values set forth in the following specification and claims can vary depending upon the desired properties sought to be obtained by the present invention. At the very least, and not as an attempt to limit the application of the doctrine of equivalents to the scope of the claims, each numerical value should at least be construed in light of the number of reported significant digits and by applying ordinary rounding techniques. Moreover, all ranges disclosed herein are to be understood to encompass the beginning and ending range values and any and all subranges subsumed therein. For example, a stated range of “1 to ID” should be considered to include any and all subranges between (and inclusive of) the minimum value of 1 and the maximum value of 10; that is, all subranges beginning with a minimum value of 1 or more and ending with a maximum value of 10 or less, e.g., 1 to 3.3, 4.7 to 7.5, 6.5 to 10, and the like. Further, as used herein, the terms “formed over”, “applies over”, “deposited over”, or “provided over” mean formed, applied, deposited, or provided on but not necessarily in contact with the surface. For example, a coating layer “formed over” a substrate does not preclude the presence of one or more other coating layers or films of the same or different composition located between the formed coating layer and the substrate.

Before discussing non-limiting embodiments of the invention, it is understood that the invention is not limited in its application to the details of the particular non-limiting embodiments shown and discussed herein since the invention is capable of other embodiments. Further, the terminology used herein to discuss the invention is for the purpose of description and is not of limitation. Still further, unless indicated otherwise in the following discussion, like numbers refer to like elements.

The non-limited embodiments of the invention discussed herein are directed to a frame for a solar module, the invention, however, is not limited thereto, and the frame of the invention can be used to frame any sheet article, e.g. but not limited to a single sheet of any material, e.g. but not limited to a glass, plastic, metal and/or wood. Further, in the following discussion, the solar module has 4 corners, however, the invention is not limited thereto, and the solar module can have more than four corners, e.g. but not limited to 5, 7, 9, or more, and can have less than 4, e.g. but not limited to 1, 2, or 3.

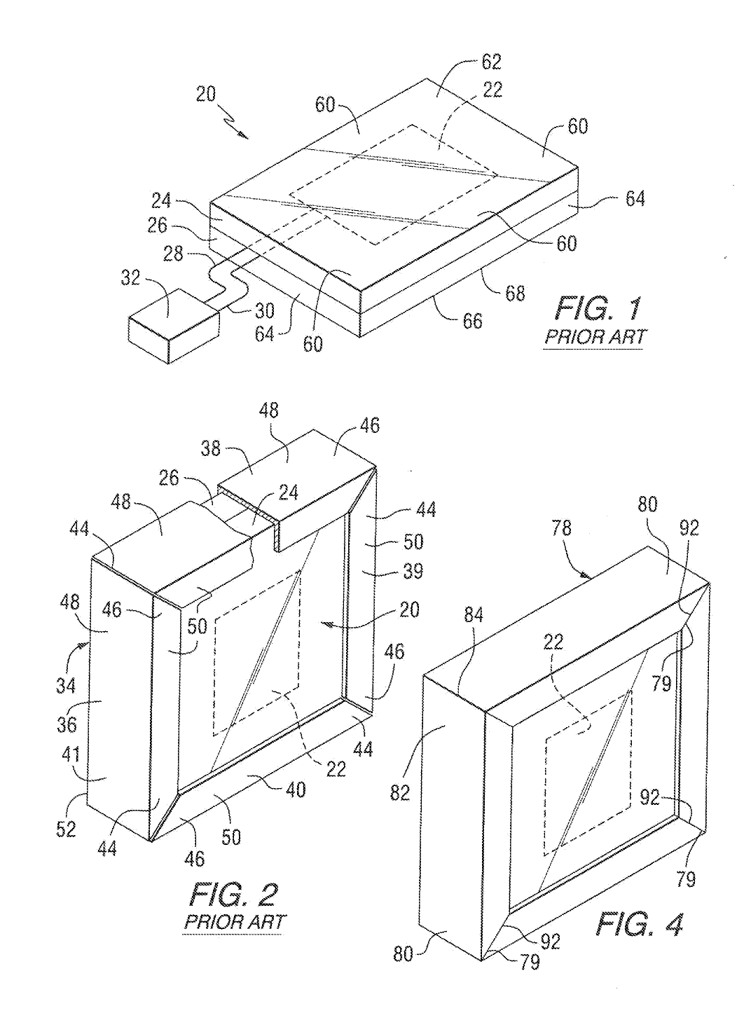

With reference to FIGS. 1 and 2, there is shown a solar module 20 (FIG. 1) including a solar cell array 22 laminated between a pair of glass sheets 24 and 26. Although not limiting to the invention, the solar cell array 22 is constructed to convert solar energy to electric energy. Wires 28 and 30 interconnect the solar cell array 22 to a junction box 32 to provide electrical accesses to the solar cell array 22. Shown in FIG. 2 is a prior art framed solar module 34. The framed solar module 34 includes the solar module 20 and a frame 36. The prior art solar frame 36 includes four extruded elongated aluminum side members 38-41 having mitered ends 44 and 46. Each of the side members 38-41 have a base 48 and a pair of upright legs 50 and 52 shaped to provide the elongated members 38-41 with a U-shape cross section. As can be appreciated, the shape of the cross section depends on the orientation of the framed module. For example and not limiting to the invention, the side member 38 as shown in FIG. 2 has an inverted U-shape; the side member 39 as shown in FIG. 2 has an inverted C-shape; the side member 40 as shown in FIG. 2 has a U-shape, and the side member 41 as shown in FIG. 2 has a C-shape. As used herein, the term “U-shaped” means that the member 40 positioned on the solar module 20 can be oriented to have a U-shape cross section.

With continued reference to FIGS. 1 and 2 as needed, the upright leg 50 of the side members 38-41 overlays marginal edge portions 60 of outer surface 62 of the glass sheet 24, the base 48 of the side members 38-41 overlays peripheral edge 64 of the solar module 20, and the upright leg 52 of the side member 38-41 overlays marginal edge portions 66 of outer surface 68 the glass sheet 26. As can now be appreciated, the marginal edge portions 60 of the sheet 24 are opposite to the marginal edge portions 66 of the sheet 26. It is noted that the base 48 of each side member ends at each corner, and the base is discontinuous at each corner of the framed module 34 as shown in FIG. 2.

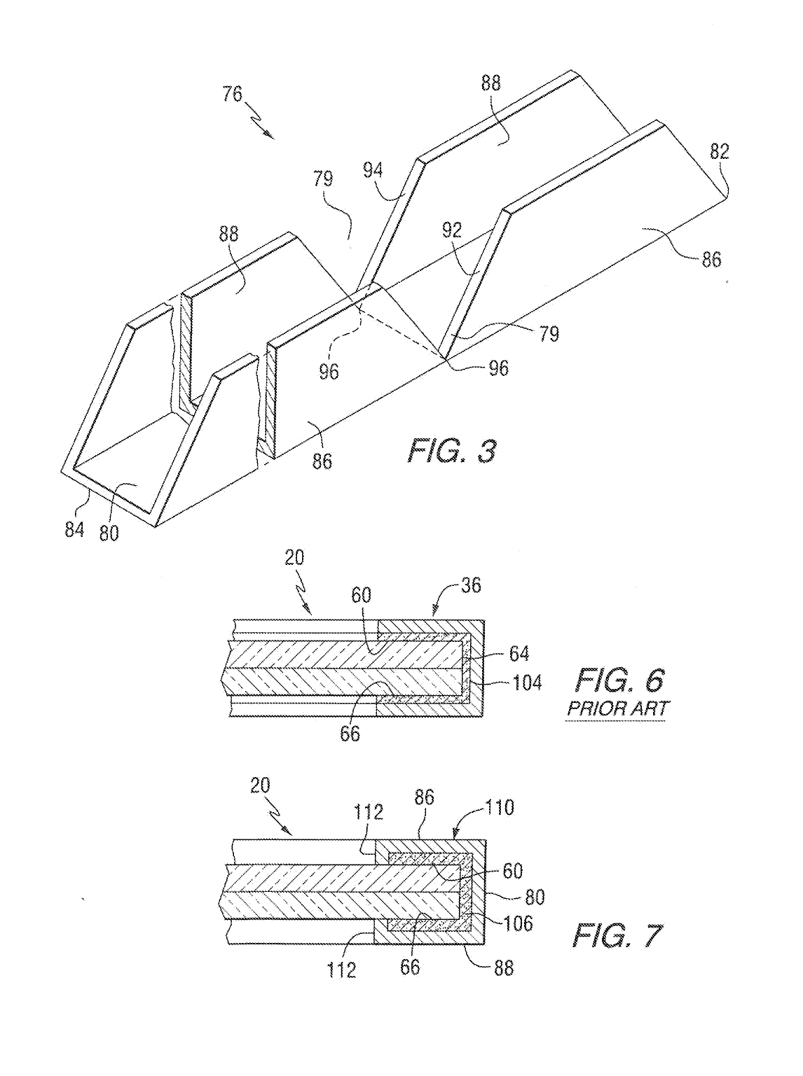

Shown in FIG. 3 is a non-limited embodiment of a segment 76 of frame or closed frame 78 (see FIG. 4) of the invention. The segment 76 shows a corner 79 of the closed frame 78 having a continuous base 80. The continuous base 80 extends from one end 82 of the closed frame 78 to opposite end 84 of the closed frame 78, and has a length preferably equal to or greater than the perimeter of the solar module 20 such that the perimeter of the solar module 20 is completely surrounded by the closed frame 78, i.e. the closed frame 78 is applied to the peripheral edge 64 and marginal edge portions 60 of the solar module 20 in the manner discussed below. The closed frame 78 further includes a pair of upright legs 86 and 88 to provide the closed frame 78 with a U-shaped cross section (see FIG. 3). Each of the upright legs 86 and 88 has a plurality V-shaped cut outs, e.g. but not limiting to the invention, the upright leg 86 having spaced cut outs similar to the cut out 92, and the upright leg 88 having spaced cut outs similar to the cut out 94, shown in FIG. 3. The length of the portion of the upright legs 86 and 88 between apexes 96 of adjacent V-shaped cut outs 92 and 94 of the legs 86 and 88, respectively of the closed frame 78 is slightly greater than the length of a side of the solar module 20 to be covered by the frame strip 76. With this arrangement the frame 78 covers the sides of the solar module 20 and the thickness of the adhesive layer 106 see FIG. 7 and discussion below.

Providing the base 80 of the frame 78 to be continuous from the end 82 to the end 84 of the closed frame 78 provides for the closed frame 78 (FIG. 4) to have no more than one corner separation instead of four corner separations as provided in the prior art and shown in FIG. 2. The ends 82 and 84 of closed frame 78 can meet at a corner of the solar module 20 or can meet between two corners of the solar module. As can now be appreciated, by those skilled in the art, when the ends 82 and 84 of the frame 78 meet at a corner of the solar module 20, the upright legs 86 and 88 of the frame 78 are mitered, and when the ends 82 and 84 of the frame strip 76 meet between adjacent corners of the solar module, the upright legs 86 and 88 preferably, but not limiting to the invention, lay in a line normal to the base 80 of the frame 78.

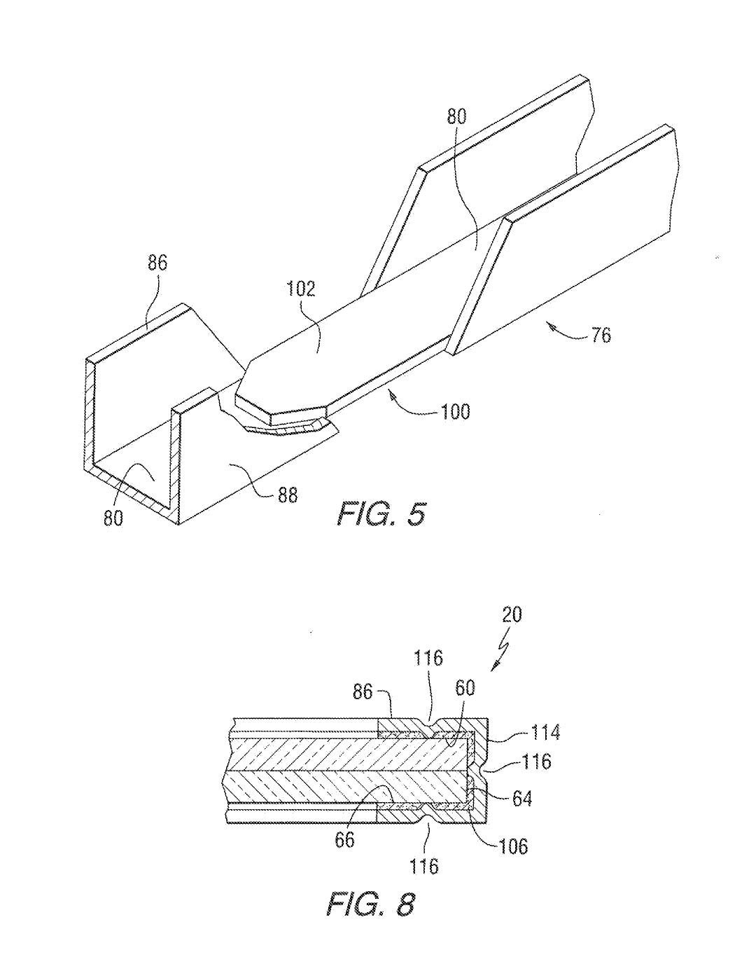

Shown in FIG. 5 is a non-limited embodiment of a closing arrangement 100 for the frame 78 of the invention. The closing arrangement 100 includes a tab 102 extending from the base 80 at the end 82 of the frame 78. The tab 102 is sized such that the tab 102 can fit between the upright legs 86 and 88 at the end 84 of the frame 78. The tab 102 can be secured to the base 80 between the upright legs 88 and 88 by a layer 106 of the pliable adhesive sealant.

The invention is not limited to the material or thickness of frame 78. In the preferred practice of the invention the frame 78 is made of a material, e.g. metal, that is moisture and gas impervious to prevent the ingress of moisture to the periphery 64 of the solar module 20, and has structural integrity to prevent damage to the edges of the solar module 20, in one non-limited embodiment of the invention, the frame strip 76 is made of 304 stainless steel coil stock having a thickness in the range of about 0.007 to 0.008 inch (0.0178-0.0203 centimeter), a width as need to extend from the marginal edge portions of one side of the solar module 20 to the marginal edge portions of the opposite side of the solar module 20 and a length sufficient to encircle the solar module 20. It is expected that the prior art leg members 38-41 have a thickness of 0.04 inch (0.102 centimeter).

With continued discussion of the instant invention, the materials of the sealant adhesive layer 106 is not limiting to the invention and are preferably a material that is moisture and/or gas impervious to prevent the ingress of moisture to the peripherial edge 64 of the solar module 20. Although not limiting to the invention, adhesives that can be used in the practice of the invention include but are not limited to butyls, silicones, and polyurethane adhesives of the type used in the art to limit or prevent moisture penetration between the frame 78 and the solar module 20. The invention may be practiced with the adhesive layer 106 having a thickness less than about 0.125 inch (0.32 cm) and more particularly, of about 0.005 inch (0.013 cm) to about 0.125 inch (0.32 cm), preferably about 0.010 inch (0.025 cm) to about 0.020 inch (0.050 cm) and most preferably about 0.015 inch (0.38 cm).

In the practice of the invention, the frame strip 76 is designed for use with the pliable layer 106 of an adhesive and/or a moisture impervious sealant. More particularly, and with reference to FIG. 6 there is shown a prior art arrangement using a double backing adhesive or a layer of a sealant adhesive 104 between the spacer frame 36 and the marginal edge portions 60 and 66, and peripheral edge portions 64 of the solar module 20. Shown in FIG. 7, is a non-limited embodiment of the invention to provide a layer 106 of a pliable adhesive and/or sealant of uniform thickness between frame 110 of the invention and the marginal edge portions 60 and 66 of the solar module 20. The frame 110 shown in FIG. 7 is similar to the frame 78 shown in FIG. 3 with the difference being the upright legs 86 and 88 each having an edge portion 112 bent toward one another over the base 80 such that the end portion 112 engages the marginal edge portions 60 and 66 of the solar module 20 to set the thickness of the sealant layer at the marginal edge portions 60 and 66 of the solar module 20.

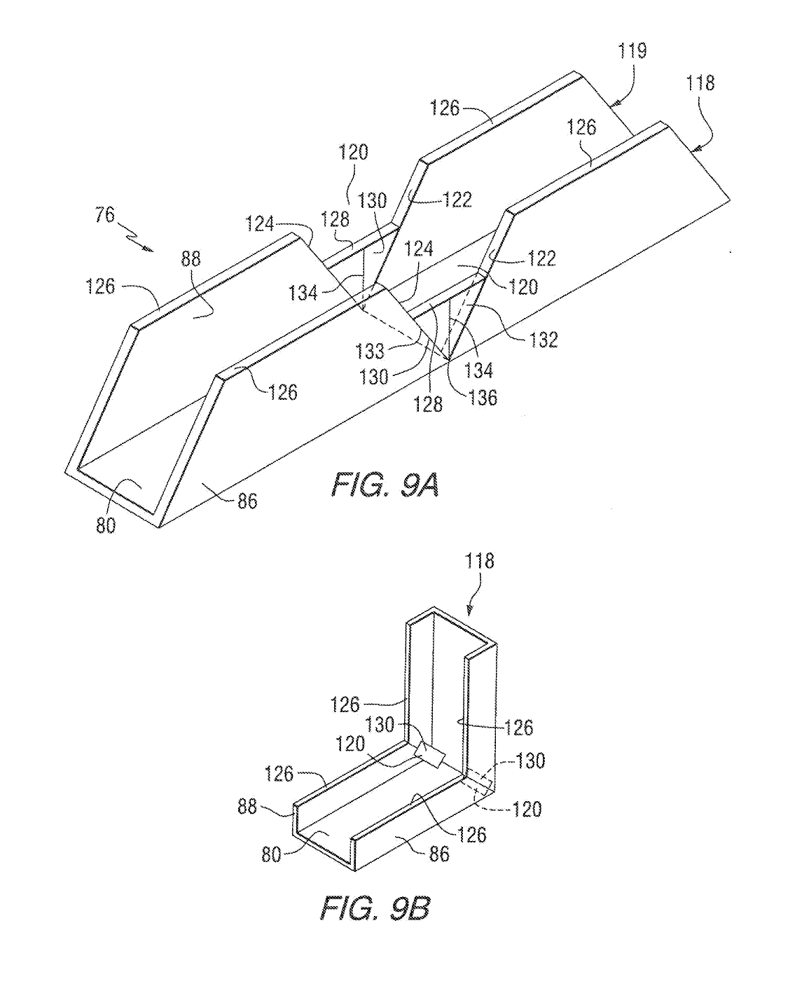

Shown in FIG. 8 is a non-limited embodiment of the invention to provide a more uniform thickness of the sealant layer 106 between frame strip 114 of the invention and the marginal edge portions 60 and 66, and the peripheral edge 64 of the solar module 20. The frame 114 shown in FIG. 8 is similar to the frame 78 shown in FIG. 3 with the difference being the upright legs 86 and 88 and the base 80 each have a plurality of spaced buttons or protuberances 116. The buttons 116 engage the marginal edge portions 60 and 66, and the peripheral edge 64 of the solar module 20 to set the thickness of the sealant layer at the marginal edge portions 60 and 66 and the peripheral edge 64 of the solar module 20. As can now be appreciated, using the buttons 116 provides a uniform thickness of sealant between the frame strip and the solar module, the thickness of the layer 106 depending on the height of the button. It has been determined that increasing the height of the buttons 116, increases the spaced distance between the apex 96 of the V-shaped cut outs 92 (see FIG. 3). This limitation can be managed by keeping the height of the button at a reduced thickness, or by using the frame 118 shown in FIGS. 9A and 98.

The invention is not limited to the method practiced to provide the frame 114, and the protuberances 116 can be stamped or punched in the frame 114, or the buttons can be adhered to the frame 114.

With reference to FIGS. 9A and 9B, there is shown a segment 119 of the frame 118. The frame 118 includes the upright legs 86 and 88, the base 80 and partial or modified shaped cutouts 120 (only two cutouts of the 6 or 8 cutouts in the continuous frame 118 shown in the segment 119; in FIG. 9). Each of the modified shaped cut outs 120 includes a pair of facing sloping edge surfaces 122 and 124 starting at edge 126 of its respective one the upright legs 86 and 88, and terminates at an elevated base 128 spaced above the base 80 of the frame 118. Portion 130 of the cut out 120 between the elevated base 128 and the base 80 has weakening lines 132-134. The weakening line 132 is an extension of the sloping line 122 of the cut out 120; the weakening line 133 is an extension of the sloping line 124 of the cut out 120, and the weakening line 134 extends from the apex 136 of the weakening lines 132 and 133 to the elevated base 128 at a midpoint between the sloping lines 122 and 124. The weakening lines 132-134 are depressions that do not go through he thickness of the upright legs 86 and 88, but are deep enough to bend the portion 130 of the cut outs 120 toward one another over the base 80 of the frame 118 as the corners 136 (see FIG. 9B, only one corner is shown) of the frame are formed. In one non-limiting embodiment of the invention the weakening lines 132-134 have a thickness in the range of equal to 50-85% of the thickness of the upright legs 86 and 88 outside of the modified cut out 120. The invention is not limited to using weakening lines in the portions 130 of the cut outs 120; however, the use of weakening lines is preferred in the practice of the invention to provide controlled bending results.

In the following discussion reference is directed to the frame 78, the discussion; however, unless indicated otherwise, is directed to all non-limited embodiments of frames discussed herein, including but not limited to the frames 110 (FIG. 7), 114 (FIG. 8), 118 (FIGS. 9A and 9B). The length of the frames is not limiting to the invention, and the invention contemplates the frames having a length equal to, or greater than the perimeter of the solar module 20 and having three V-shaped cut outs 79. In this manner, the tab 102 of the frame 78 is positioned in the end 84 of the frame 78 at the fourth corner and secured in position by the adhesive and/or sealant layer 106. Optionally each of the upright legs 86 and 88 of the frame can be provided with four cutouts 120 and the ends 82 and 84 of the frame 78 connected at a position between two corners of the solar module 20 as discussed above.

The invention contemplates using one or more non-limiting embodiments of the invention with the frames 78, 110, 114 and 118 of the invention, e.g. but not limiting to the invention, the buttons 116 used on the frame 114 shown in FIG. 8 to provide a uniform thickness of the layer 106 of the pliable sealant can be used with the bent portion 112 of the closed frame 110 shown in FIG. 7 to prevent the layer 106 of the pliable adhesive from being squeezed out from between the frame and the solar module 20 when the frame is wrapped around the peripheral edges of the solar module and pressed against the solar module 20, or when the edges of the solar module 20 is moved between the upright legs 86 and 88 of the frame 114.

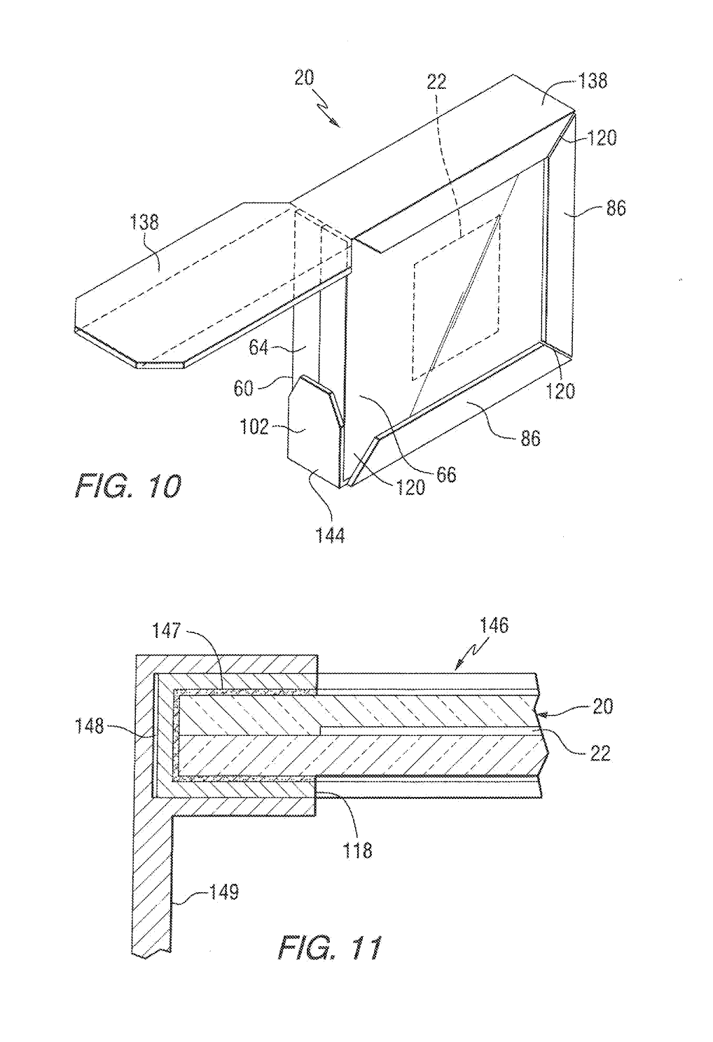

The invention is not limited to the method of applying the frame to the solar module 20, and any method known in the art, e.g. but not limited to the methods disclosed in U.S. Pat. No. 5,313,761, which patent in its entirety is hereby incorporated by reference can be used in the practice of the invention. With reference to FIG. 10, in one non-limiting embodiment of the invention, a metal strip is punched (punched strip identified as number 138 in FIG. 10) to have three of the V-shaped cut outs 79 on portions of the strip designated to be the upright legs 86 and 88. The layer 106 of the sealant is applied to a surface portion of the strip 138 designated to face the solar module 20. The portion of the punched strip 138 having the tab 102 is positioned at one of the corners of the solar module, and the tab 102 is bent over a corner 144 of the solar module 20 as shown in FIG. 10. The frame is formed from the strip 138 at each side of the solar module by biasing the portion of the strip 138 designated to be the base 80 against the peripheral edge 60 of the solar module 20. The portions of the punched strip 138 designated to be the upright legs 86 and 88 are thereafter biased against the marginal edge portions 66 of the solar module 20 (see FIG. 10). The above is repeated until the frame completely surrounds the peripheral edge 60 and the marginal edge portions 66 of the solar module 20.

In another non-limited embodiment of the invention, the frame is applied to the edges of the solar module 20 by applying the sealant layer 106 to the strip 138 and biasing the portion of the strip 138 designated to be the base 80 against the peripheral edge 60 of the solar module 20. After the base 80 is biased against the peripheral edge 60 of the solar module 20, and the V-shaped cut outs 79 (see FIG. 3) are positioned at the corners of the solar module 20, the portions of the strip 138 designated to form the upright legs 86 and 88 are biased against the marginal edge portions of the solar module. In still another non-limited embodiment of the invention, the frame 78 is mounted on the edges of the solar module 20 by bending the punched strip 138 to form the frame 78 with a V-shaped cross section. The method of bending the punched strip 138 to form the frame with a V-shaped cross section can be done with any known technique known in the art, such as roll forming. The space between the upright legs is filled with the layer 106 of the sealant, and a side of the solar module moves between the upright legs 86 and 88. The tab 102 is bent against peripheral edge of the solar module 20. Thereafter, the second side of the solar module is moved between the spaced upright legs of the frame, followed by biasing the third side of the solar module between the upright legs of the frame, followed by biasing the fourth side of the solar module between the upright legs of the frame to encase the peripheral edge and the marginal edge portions of the frame and to cover the tab 102 (see FIG. 10).

The layer 106 of the pliable sealant can be injected into the frame of the invention, e.g. but not limited to the frame 78 and/or 118 before bending the frame, or after bending the frame but before the frame is assembled around the perimeter of the solar module 20, Coated coil stock could be used as well to provide color coordinated frame designs which match roof or other surroundings. The frames of the invention can be made from any material that can be roll formed and hold its shape, for example stainless steel coil stock.

Shown in FIG. 11 is a framed solar module 146 having the frame strip 118 (see FIGS. 9A and 9B) and the solar module 20. Edge 147 of the framed solar module 146 is mounted in groove 148 of a structure 149 of the prior art for positioning the solar modules facing and optionally tracking the solar source, e.g. but not limited to the sun. The need of a layer of a moisture resistant or moisture impervious adhesive between the structure 149 and the edge 147 of the framed solar module 146 is eliminated by proving a layer of moisture impervious sealant between the frame 118 and the marginal edge portions and peripheral edge of the solar module 20.

The non-limiting embodiments of the invention discussed above are generally directed to, but not limited to, frames for a solar module. The following non-limited embodiments of the invention are generally directed to, but not limited to, frames for solar modules that have an added feature for stacking the framed solar modules for storage and shipment, and for assembling the framed modules on racks to face a source of solar energy, e.g. but not limited to the sun (not shown). In the following discussion the frame 78 of the invention is modified to include additional embodiments of the invention; however, the invention is not limited thereto and any of the frames, e.g. but not limited to the frame 110 (FIG. 7), the frame 114 (FIG. 8) and the frame 118 (FIG. 9) discussed above can be used in the following discussion.

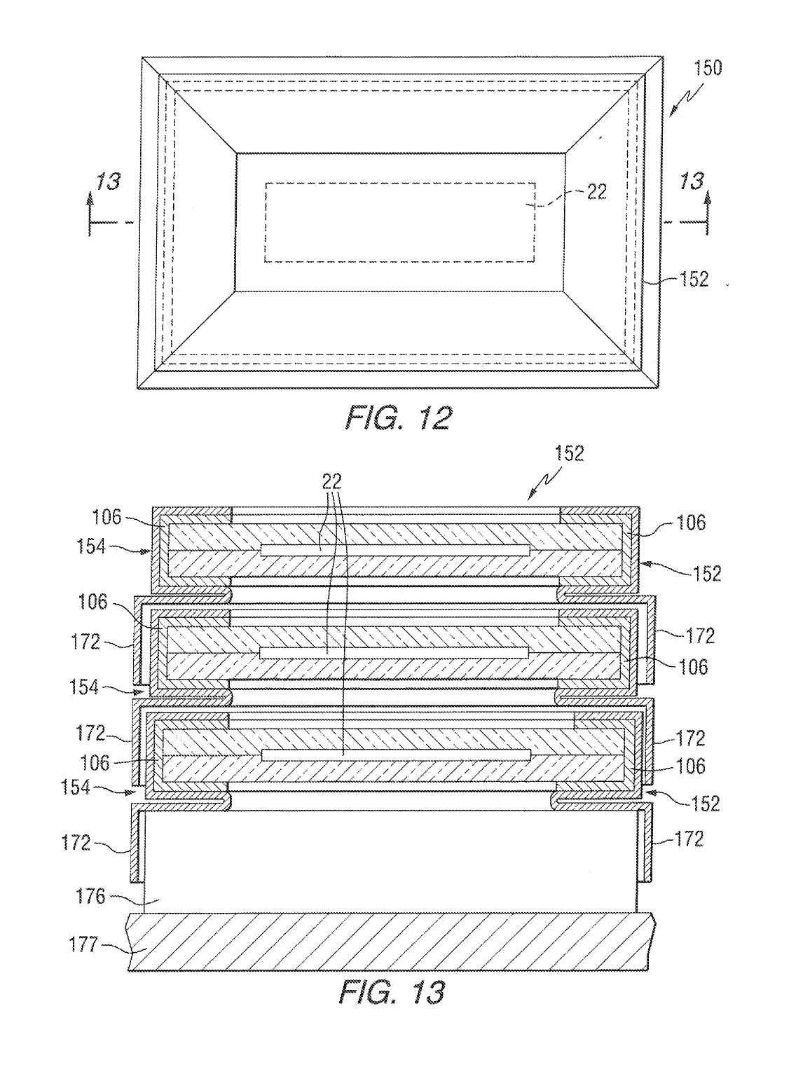

As is appreciated by those skilled in the art, solar module manufacturers typically purchase special corner pieces, usually made of plastic, for use to ship the solar modules 20. One of these corner pieces is fitted to each corner of each module and allows the modules to be stacked on a pallet and nested together to prevent shifting of the stack during shipment and/storage. With reference to FIGS. 12 and 13 as needed, there is shown framed solar modules 150 arranged in a stack 152 in accordance to the invention. As is appreciated by those skilled in the art of transporting and storing glass, the glass sheets or laminated glass sheets can be stacked on edge with the major surface of the glass sheets in a generally vertical position (5-15 degrees from the normal), or with the major surface of the glass sheets in a horizontal position as shown in FIGS. 12 and 13.

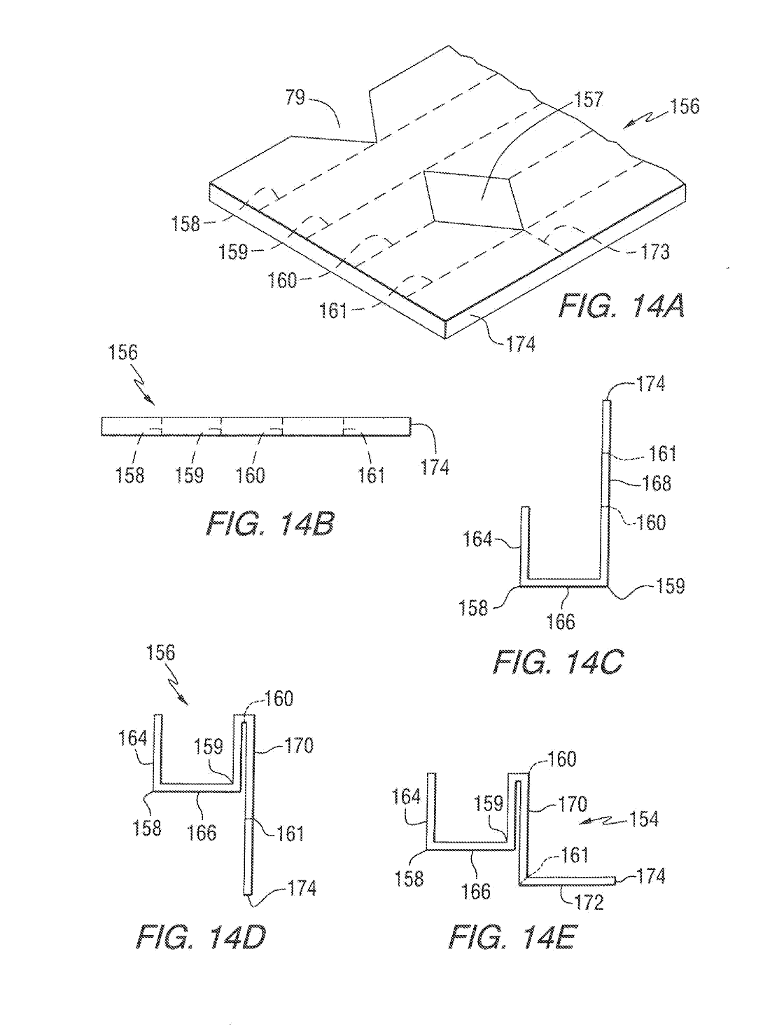

FIGS. 14A-14E, illustrate steps in the making a non-limited embodiment of a spacer frame 154 of the invention having a retention member 172 for stacking framed solar modules 152. With reference to FIGS. 14A-14E as needed, a section 156 of a stainless steel coil stock (the stainless steel coil stock not shown) having imaginary bend lines 158-161 along which the section 156 is bent. The section 156 is punched to provide the V-shaped cut outs 79 (see FIG. 3). In FIG. 14A, the V-shaped cut out 79 is punched to provide a diamond shaped cut out 157. The diamond shaped cutout 157 provides a V-shaped cut out 79 in a manner discussed below. It is understood that the section 156 showing the V-shaped cutouts can be punched to have the cut outs 120 (see FIG. 9). FIG. 14B shows a side view of the section 156 of FIG. 14A with the imaginary bend lines 158-161. FIG. 14C shows the section 156 bent along bend lines 158 and 159 to provide vertical leg 164 having the cut out 79 (shown in FIG. 3), base 166 and vertical portion 168 of the section 156 having bend lines 160 and 161, and the diamond shaped cut out 157. FIG. 14D shows the section 156 bent along bend line 160 back over the portion of the section 156 between the bend lines 159 and 160 such that the portion of the section 156 between the imaginary bend lines 159-161 provide second vertical leg 170 having the cut out 79 with the imaginary bend line 161 extending beyond the base 166 for reasons discussed below. FIG. 14E shows the section 156 bent along the imaginary bend line 161 to provide retention member 172 and the cross section of frame 154.

With reference to FIG. 13 the framed solar modules 152 are stacked one on top of the other in any convenient manner. For example, and not limiting to the invention, the retention member 172 of the bottom framed solar module 152 is placed around a block or pallet 176 having the same shape and size as the framed solar modules 152 and secured to a floor 177 of a transportation vehicle (not shown), e.g. but not limited to a truck or a railcar. The retention member 172 of the next to be stacked framed solar module is place around the base 166 of the frame of the previously stacked framed solar module 152. The process is repeated until a stack 150 of framed solar modules is completed, Restraints are applied to the stack 150 to unitize the stack 150.

In one non-limited embodiment of the invention, the retention member 172 is continuous (forms an enclosed cavity) which limits sideward motion of the stacked framed solar modules. In the instance when the retention member 172 is continuous, the length of the second vertical leg 170 (see FIGS. 14E) is increased to increase the opening of the cavity formed by the retention member 172 for ease of placing one framed solar module over an underlying framed solar module. The invention also contemplates having a retention leg member 172 associated with each side of the framed solar module, and the retention leg member 172 associated with a side of the frame spaced from one another. This can be realized by providing a cut line 173 (shown in phantom in FIG. 14A) in the section 156, the cut line extending from the diamond shape cut out 157 to edge 174 of the section 156. In the instance when the retention leg members are spaced from one another, opposite ones of the retention leg members 172 are angled toward one another to engage the underlying framed solar module.

As can now be appreciated, the retention leg members and retention member 172 of the frame 154 prevent sideward motion of the framed solar modules without the expense of the corner pieces presently used. As mentioned above and shown in FIG. 14E, the length of the section between the bend lines 159 and 160 is shorter than the length of the section between the imaginary bend lines 160 and 161 for ease of sliding the retention leg members and retention legs 172 over the underlying framed solar module (see FIG. 13). The difference is not limiting to the invention and in one embodiment of the invention the difference in length between the section between the bend lines 160 and 161 and the section between the bend lines 159 and 160 is in the range of greater than zero to ½ inch, or stated another way the section between the bend lines 161 and 162 extends beyond the base 166 by a length in the range of greater than zero to ½ inch. In one non-limiting embodiment of the invention, the length of the retention leg member and retention member 172 is not greater than the width of the base of the underlying framed solar module.

As can further be appreciated, one surface of the solar module is designated to face the source of solar energy. The invention is not limited to the side of the framed solar module having the retention leg 172. In the preferred practice of the invention, the retention leg 172 extends from the surface of the framed solar module designated to face away from the source of the solar energy. By way of illustration and not limiting to the invention, if the surface 60 of the solar module is designated to face the source of solar energy, the retention leg member or the retention member 172 preferably extends away from the surface 66 of the solar module 20. In this manner, the framed solar module having the retention leg member or the retention member 172 can use the retention legs 172 to secure the framed soar module 152 on a mounting platform to face the source of solar energy.

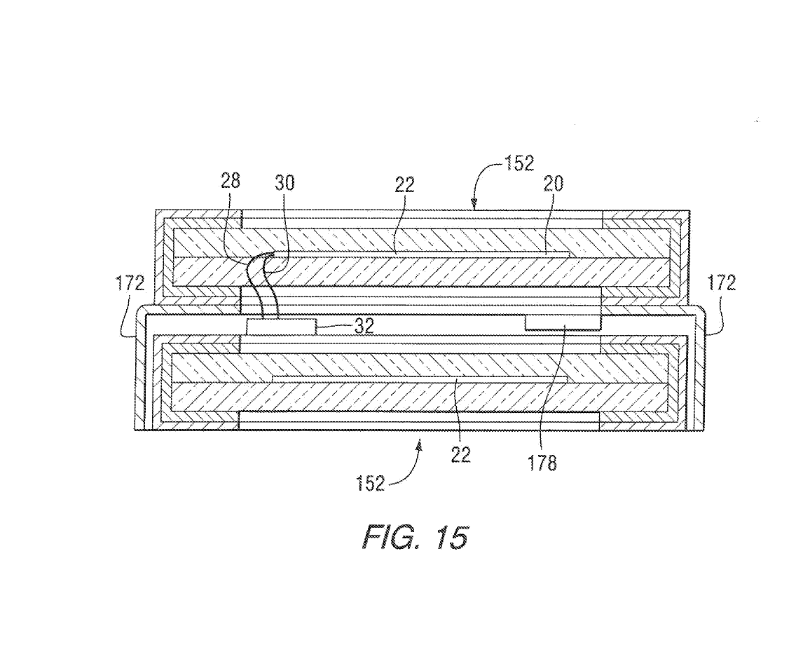

The stacking arrangement of the framed solar modules shown in FIGS. 12 and 13 is preferably made without the junction box 32 (see FIG. 1) connected to the solar cell array 22 of the solar module 20. In those instances when the stacking arrangement includes the junction box 32, additional dunage 178 shown in FIG. 15 is used to level the stacked framed solar modules 152. Further, the invention contemplates placing the junction box 32 wrapping that can serve as dunage.

While a preferred embodiment of the invention has been illustrated and described in detail, the present invention is not to be considered limited to the precise construction disclosed. Various adaptations, modifications and uses of the invention may occur to those skilled in the art to which the invention relates and the intention is to cover hereby all such adaptations, modifications and uses which fall within the spirit or scope of the appended claims.

What is claimed is:

1. A framed solar module comprising:
a solar module comprising an energy converter between a pair of sheets laminated together, the solar module having a peripheral edge, and marginal edge portions, wherein the energy converter converts solar energy to non-solar energy;
a frame having a base, a first leg, a second leg, a first end and a second end, wherein the base, the first leg and the second leg are joined together with the first leg and the second leg in facing relationship to, and spaced from, one another to provide the frame with a U-shape cross section to mount the frame over the peripheral edge, and the marginal edge portions, of the solar module, wherein the first end and the second end of the frame are joined together and the base of the frame is continuous from the first end to the second end of the frame;
a layer of a pliable adhesive and/or a moisture resistant sealant between inner surface of the frame and the peripheral edge, and the marginal edge portions, of the solar module, and
a spacer acting on the frame to limit movement of the frame toward the peripheral edge, and the marginal edge portions, of the solar module to provide the layer of the pliable adhesive and/or a moisture resistant sealant with a uniform thickness between the frame and the solar module.

2. The framed solar module according to claim 1, wherein the frame is a closed frame, and the solar module has a plurality of corners and each of the first leg and the second leg of the frame have spaced V-shaped cutouts, wherein one of the V-shaped cut out of the first leg and corresponding one of the V-shaped cut outs of the second leg are at a selected one of the corners of the solar module.

3. The framed solar module according to claim 2 wherein the first end and the second end of the closed spacer frame are joined by an arrangement selected from the group of a corner key, and a tab extending from the base of the frame at the first end of the frame, the tab sized to fit between the first leg and the second leg at the second end of the frame.

4. The framed solar module according to claim 2, wherein the solar module has four corners designated corner one, corner two, corner three and corner four, the first leg has three V-shape cut outs designated as 1-1, 1-2 and 1-3, and the second leg has three V-shape cut outs designated as 2-1, 2-2 and 2-3, wherein the V-shape cut outs 1-1 and 2-1 are at the corner one of the solar module, the V-shape cut outs 1-2 and 2-2 are at the corner two of the solar module, the V-shape cut outs 1-3 and 2-3 are at the corner three of the solar module, and the first end and the second end of the closed frame are joined at the fourth corner.

5. The framed solar module according to claim 2, wherein the solar module has four corners designated corner one, corner two, corner three and corner four, the first leg has four V-shape cut outs designated as 1-1, 1-2, 1-3 and 1-4, and the second leg has four V-shape cut outs designated as 2-1, 2-2, 2-3 and 2-4, wherein the V-shape cut outs 1-1 and 2-1 are at the corner one of the solar module, the V-shape cut outs 1-2 and 2-2 are at the corner two of the solar module, the V-shape cut outs 1-3 and 2-3 are at the corner three of the solar module, the V-shaped cut outs 1-4 and 2-4 are at the corner four of the solar module, and the first end and the second end of the closed frame are joined at a position between corner one and corner four of the solar module.

6. The framed solar module according to claim 1 wherein the spacer comprises a plurality of spaced protuberances formed on the inner surface of the closed frame, and the protuberances engage the peripheral edge and the marginal edge portions of the solar module to provide the layer of the pliable adhesive and/or a moisture resistant sealant with a uniform predetermined thickness.

7. The framed solar module according to claim 6 wherein the spacer further comprises edge of the first leg and edge of the second leg bent toward one another over the base and engaging outer surfaces of the solar module to provide the layer of the pliable adhesive and/or a moisture resistant sealant with a uniform predetermined thickness between the first leg and the second leg of the closed frame and the solar module.

8. The framed solar module according to claim 1 wherein the spacer comprises edge of the first leg and of the second leg bent toward one another over the base and engaging surface of the solar module to provide the layer of the pliable adhesive and/or a moisture resistant sealant with a uniform thickness between the first leg and the second leg of the closed frame and the solar module.

9. The framed solar module according to claim 1, wherein the energy converter of the solar module is a plurality of solar cells to convert the solar energy to electric energy.

10. The framed solar module according to claim 1 wherein each of the cut outs of the first leg and of the second leg has a first sloping surface and an opposite second sloping surface, the distance between the first sloping surface and the second sloping surface of the cut outs of the first leg and of the second leg decreasing as the distance from the base decreases, the first sloping surface and the second sloping surface of the cut outs of the first leg and second leg terminating at a spaced distance from the base of the frame defined as a termination edge, a first portion of the first leg and a second portion of the second leg between the base of the frame and the termination edge of the first leg and the second leg respectively, the first portion of the cut outs of the first leg having a first weakening fine extending from the first sloping surface to the base, a second weakening line extending from second sloping surface to the base, and a third weakening line, wherein the distance between the first weakening line and second weakening line of the first portions of the first leg decreases as the distance from the base decreases, and the first weakening line and the second weakening line meet at the base, and the third weakening line extends from the jointure of the first and second weakening line to the edge of the first portion, and the second portion of the cut outs of the second leg having a first weakening line extending from the first sloping surface of the cut outs of the second leg to the base of the frame, a second weakening line extending from second sloping surface of the cut outs of the second leg to the base, and a third weakening line, wherein the distance between the first weakening line and second weakening line of the second portion of the cut outs of the second leg decreases as the distance from the base decreases, and the first weakening line and the second weakening line of the second portion of the cut outs of the second leg meet at the base of the frame, and the third weakening line of the second portion of the cut outs of the second leg extends from the jointure of the first and second weakening line of the second portion to the termination edge of the second portion, wherein with the frame wrapped around the solar module, the first portion of each of the cutouts of the first leg, and the second portion of each of the cutouts of the second leg, are bent toward each other over the base.

11. The framed solar module according to claim 10 wherein a plurality of spaced protuberances formed on the inner surface of the closed frame, and the protuberances engage the peripheral edge and the marginal edge portions of the solar module to provide the layer of the pliable adhesive and/or a moisture resistant sealant with a uniform predetermined thickness.

12. The framed solar module according to claim 11, wherein the spacer comprises edge of the first leg and of the second leg bent toward one another over the base and engaging surface of the solar module to provide the layer of the pliable adhesive and/or a moisture resistant sealant with a uniform thickness between the first leg and the second leg of the closed frame and the solar module.

13. A framed solar module comprising:
a first solar module comprising an energy converter between a pair of laminated sheets, wherein the energy converter converts solar energy to non-solar energy, and
a frame having a first leg member, a second leg member, a third leg member, a first end, a second end, and a retention leg member wherein the first leg member and the third leg member are joined to the second leg member with the first leg member and the third leg member in facing relationship to one another and spaced from one another to provide a first sub frame having an inner channel, wherein the marginal edge portions and the peripheral edge of the solar module are retained in the inner channel of the first sub frame and, wherein outer surface of the base of the first sub frame lies in a first plane and outer surface of the retention leg member lies in a second plane, the first plane and the second plane generally parallel to one another, with the retention leg member connected to the first sub frame and extending away from the solar module retained in the inner channel of the first sub frame to provide a cavity sized to receive a second sub frame of a second framed module or a stack retention base.

14. The framed solar module according to claim 13, wherein the frame is shaped from a single piece of metal coil stock to have a cross section comprising the first leg member, the second leg member having one side joined to the first leg member and an opposite side of the second member joined to a segment of the piece sized to form the third leg member and the retention leg member; the segment of the piece and the first leg member are in facing relationship to one another and spaced from one another, the segment is bent back along its length to provide the third leg member and the first sub frame, a portion of the bent back member extends beyond the second leg member of the first sub frame and remaining portion of the segment is shaped to lie in the second plane.

15. The framed solar module according to claim 14, wherein the solar module has four corners and the single piece of metal coil stock has a V-shaped cut out for at least three corners in the first leg member and has a diamond shaped cut out for at least three corners in the third leg member.

16. The framed solar module according to claim 15 wherein a third portion of the single piece of metal coil stock designated to provide the retention leg member has a cut out to separate the retention leg members at the corners of the solar module.

17. The framed solar module according to claim 13 wherein the framed solar module is a framed solar module of a stack of framed solar modules and each of the framed solar modules in the stack comprises a retention leg member and the cavity provided by the retention leg member, wherein lower most framed solar module of the stack of framed solar module is mounted on a loading block with the loading block in the cavity of the lower most framed solar module provided by the retention leg member of the lower most framed solar module, and the remaining framed solar modules mounted one on top of the other with the sub frame of the bottom retention leg member in the cavity formed by the retention leg members of the upper framed solar module.

18. The framed solar module according to claim 13 wherein the frame is a closed framed and the second leg member is continuous from the first end to the second end.

19. The framed solar module according to claim 13, wherein the solar module has at least one corner and a glass sheet, and the first leg member and the third leg member of the first sub frame at the corner has a modified cut out, the modified cut out of the first leg member and of the third leg member has a first sloping surface and an opposite second sloping surface, the distance between the first sloping surface and the second sloping surface of the modified cut out of the first leg member and of the third leg member decreasing as the distance from the second leg member decreases, the first sloping surface and the second sloping surface of the modified cut outs of the first leg member and the third leg member terminating at a spaced distance from the second leg member of the first sub frame defined as a termination edge, a first portion of the first leg member and a second portion of the third leg member between the second leg member of the sub frame and the termination edge of the first leg member and the third leg member respectively, the first portion of the modified cut outs of the first leg member having a first weakening line extending from the first sloping surface to the second leg member, a second weakening line extending from second sloping surface to the second leg member, and a third weakening line, wherein the distance between the first weakening line and second weakening fine of the first portions of the first leg member decreases as the distance from the second leg member decreases, and the first weakening line and the second weakening line meet at the second leg member, and the third weakening line extends from the jointure of the first and second weakening line to the edge of the first portion, and the second portion of the modified cut outs of the third leg member having a first weakening line extending from the first sloping surface of the modified cut outs of the third leg member to the second leg member of the first sub frame, a second weakening line extending from second sloping surface of the cut outs of the third leg to the second leg member, and a third weakening line, wherein the distance between the first weakening line and second weakening line of the second portion of the modified cut outs of the third leg decreases as the distance from the second leg member decreases, and the first weakening line and the second weakening fine of the second portion of the modified cut outs of the third leg member meet at the second leg member of the first sub frame, and the third weakening line of the second portion of the modified cut outs of the third leg extends from the jointure of the first and second weakening line of the second portion to the termination edge of the second portion, wherein with the first sub frame wrapped around the solar module, the first portion of each of the modified cutouts of the first leg member, and the second portion of each of the modified cutouts of the third leg member, are bent toward each other over the second leg member.

20. The framed solar module according to claim 13, wherein the cavity formed by the retention leg member is a continuous walled cavity, the leg retention members providing the wall.

21. A method of mounting a solar module to receive solar energy, comprising:
constructing a framed solar module comprising:
a first solar module comprising an energy converter between a pair of laminated sheets, wherein the energy converter converts solar energy to non-solar energy, and
a frame having a first leg member, a second leg member, a third leg member, a first end, a second end, and a retention leg member wherein the first leg member and the third leg member are joined to the second leg member with the first leg member and the third leg member in facing relationship to one another and spaced from one another to provide a sub frame having an inner channel, wherein the marginal edge portions and the peripheral edge of the solar module are retained in the channel of the sub frame and, wherein outer surface of the base of the sub frame lies in a first plane and outer surface of the retention leg member lies in a second plane, the first plane and the second plane generally parallel to one another, with the retention leg member connected to the sub frame and extending away from the retained solar module to provide a cavity sized to receive a mounting block of an array of mounting blocks;
constructing an array of mounting blocks facing or tracking a source of solar energy, each of the mounting blocks having a predetermined shape and dimensions to fit into the cavity provided by the retention leg member of the first sub frame:
mounting a framed solar module on each of the mounting blocks with the mounting block positioned in the cavity of the retention leg member, and
securing the framed solar module to the mounting block.
